(19) United States
(12) Patent Application Publication
(10) Pub. No.: US 2026/0136839 A1
(43) Pub. Date: May 14, 2026

(54) MAGNETIC MEMORY DEVICE AND METHOD FOR MANUFACTURING THE SAME

(71) Applicant: TAIWAN SEMICONDUCTOR MANUFACTURING COMPANY, LTD., Hsinchu (TW)

(72) Inventors: Hung-Yi TSAI, Hsinchu (TW); Harry-Haklay CHUANG, Hsinchu (TW); Hung Cho WANG, Hsinchu (TW); Sheng-Huang HUANG, Hsinchu (TW); Sheng-Chang CHEN, Hsinchu (TW)

(73) Assignee: TAIWAN SEMICONDUCTOR MANUFACTURING COMPANY, LTD., Hsinchu (TW)

(21) Appl. No.: 18/946,396

(22) Filed: Nov. 13, 2024

(51) Int. Cl. H10N 50/01; H10B 61/00; H10N 50/10

(52) U.S. Cl. CPC H10N 50/01; H10B 61/10; H10N 50/10

(57) ABSTRACT

A method for manufacturing a memory device includes: forming a memory unit that includes a bottom electrode, an MTJ element disposed on the bottom electrode, and a top electrode disposed on the MTJ element; forming an etch stop layer over the memory unit, wherein the etch stop layer is disposed along a top surface and a side surface of the memory unit, and is made of a silicon compound; forming an etching end detection layer on the etch stop layer, wherein the etching end detection layer is made of a nitride; forming a dielectric layer on the etching end detection layer; and removing a horizontal portion of each of the dielectric layer, the etching end detection layer and the etch stop layer, so as to expose the top surface of the memory unit.

### BACKGROUND

Magnetic tunnel junction (MTJ) is a core component in several applications including read-heads of hard disk drives, sensors, and magneto-resistive random access memory (MRAM). Among them, MRAM is an emerging non-volatile memory that is advantageous in having ultra-low power consumption and being easily integrated with logic circuits. Nevertheless, there is still a need to modify the structure of MRAM and the method to manufacturing MRAM so as to reduce cost of MRAM and improve yield of MRAM.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view of a memory device in accordance with some embodiments.

FIG. 2 is a flow chart illustrating a method for manufacturing a memory device in accordance with some embodiments.

FIGS. 3 to 11 are schematic sectional views illustrating intermediate stages of a method for manufacturing a memory device in accordance with some embodiments.

FIG. 12 is a schematic sectional view of a memory device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

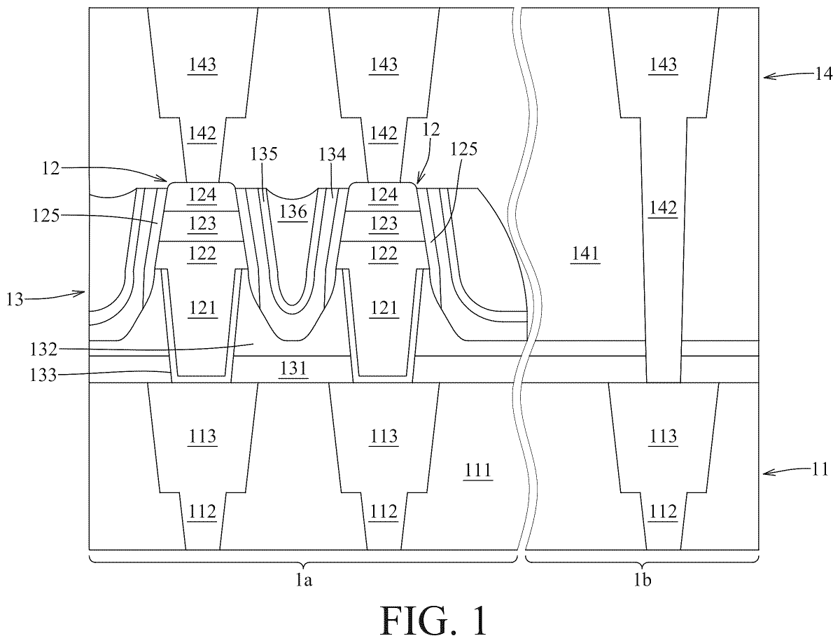

FIG. 1 is a schematic sectional view of a memory device in accordance with some embodiments. Referring to FIG. 1, the memory device is a magneto-resistive random access memory (MRAM) device, has a device memory region (1a) and a device peripheral region (1b), and includes a first interconnect structure 11, a plurality of memory units 12, a separating feature 13 and a second interconnect structure 14. In some embodiments, the device peripheral region (1b) is a logic region.

The first interconnect structure 11 includes a dielectric layer 111, a plurality of conductive vias 112 and a plurality of conductive lines 113. The dielectric layer 111 extends throughout the device memory region (1a) and the device peripheral region (1b). The conductive vias 112 are formed in a lower portion of the dielectric layer 111, with some of the conductive vias 112 disposed in the device memory region (1a) and some of the conductive vias 112 disposed in the device peripheral region (1b). The conductive lines 113 are formed in an upper portion of the dielectric layer 111, with some of the conductive lines 113 disposed in the device memory region (1a) and some of the conductive lines 113 disposed in the device peripheral region (1b). Each of the conductive vias 112 is aligned with and connected to a corresponding one of the conductive lines 113.

The memory units 12 are disposed on the first interconnect structure 11 and in the device memory region (1a), and each include a bottom electrode via 121, a bottom electrode 122, a magnetic tunnel junction (MTJ) element 123 (i.e., a data storage element), a top electrode 124 and a spacer 125. With respect to each of the memory units 12, the bottom electrode via 121 is aligned with a corresponding one of the conductive lines 113 that are disposed in the device memory region (1a), the bottom electrode 122 is disposed on the bottom electrode via 121, the MTJ element 123 is disposed on the bottom electrode 122, the top electrode 124 is disposed on the MTJ element 123, the spacer 125 covers a side surface of each of the bottom electrode 122, the MTJ element 123 and the top electrode 124, and a top surface of the spacer 125 is substantially lower than a top surface of the top electrode 124.

The separating feature 13 is configured to separate the memory units 12 from each other, and includes a barrier layer 131, a dielectric layer 132, a barrier film 133, two capping films 134, 135 and a dielectric element 136. The barrier film 133 covers side and bottom surfaces of the bottom electrode via 121 of each of the memory units 12. The bottom electrode via 121 of each of the memory units 12 is electrically connected to the corresponding conductive line 113 through the barrier film 133. The barrier layer 131 is disposed on the first interconnect structure 11, covers a portion of a top surface of the first interconnect structure 11 that is exposed from the barrier film 133, and further covers portions of the barrier film 133 that cover lower portions of the bottom electrode vias 121 of the memory units 12. The dielectric layer 132 is disposed on the barrier layer 131, and covers portions of the barrier film 133 that cover upper portions of the bottom electrode vias 121 of the memory units 12. The dielectric element 136 laterally surrounds the spacers 125 of the memory units 12. The capping films 134, 135 are disposed between the dielectric element 136 and a combination of the memory units 12. The capping film 135 covers side and bottom surfaces of the dielectric element 136. The capping film 134 covers the capping film 135, and is in contact with the spacers 125 of the memory units 12. A top surface of each of the capping films 134, 135 and the dielectric element 136 is substantially lower than the top surfaces of the top electrodes 124 of the memory units 12.

The second interconnect structure 14 is disposed on the memory units 12 and the separating feature 13, and includes a dielectric layer 141, a plurality of conductive vias 142 and a plurality of conductive lines 143. The dielectric layer 141 extends throughout the device memory region (1a) and the device peripheral region (1b). The conductive vias 142 are formed in a lower portion of the dielectric layer 141, with some of the conductive vias 142 disposed in the device memory region (1a) and some of the conductive vias 142 disposed in the device peripheral region (1b). The conductive lines 143 are formed in an upper portion of the dielectric layer 141, with some of the conductive lines 143 disposed on the device memory region (1a) and some of the conductive lines 143 disposed in the device peripheral region (1b). Each of the conductive vias 142 that are disposed in the device memory region (1a) is aligned with and connected to a corresponding one of the top electrodes 124 of the memory units 12 and a corresponding one of the conductive lines 143 that are disposed in the device memory region (1a). Each of the conductive vias 142 that are disposed in the device peripheral region (1b) penetrates the dielectric layer 132 and the buffer layer 131, and is aligned with and connected to a corresponding one of the conductive lines 113 that are disposed in the device peripheral region (1b) and a corresponding one of the conductive lines 143 that are disposed in the device peripheral region (1b).

In some embodiments, the capping film 134 may be made of, for example, a silicon compound that does not contain nitrogen (N) atoms, such as silicon oxycarbide or the like. Other suitable materials are within the contemplated scope of the present disclosure.

In some embodiments, the capping film 135 may be made of, for example, a nitride, such as a silicon compound that contains nitrogen atoms (e.g., silicon nitride, silicon oxynitride or the like). Other suitable materials are within the contemplated scope of the present disclosure.

In some embodiments, the dielectric element 136 may include, for example, an oxide and tetra-ethyl-ortho-silicate (TEOS). Other suitable materials are within the contemplated scope of the present disclosure.

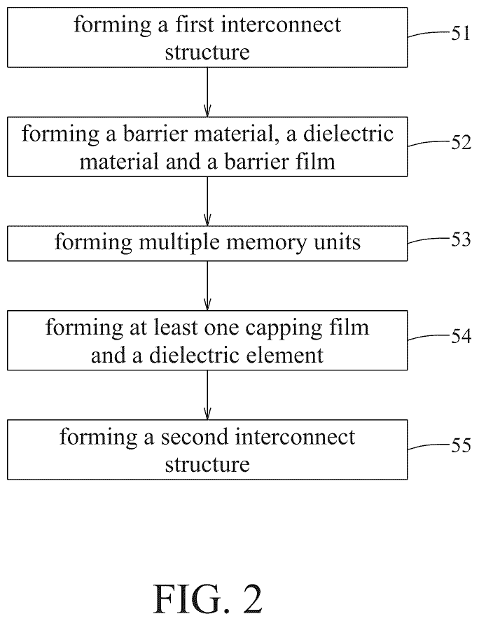

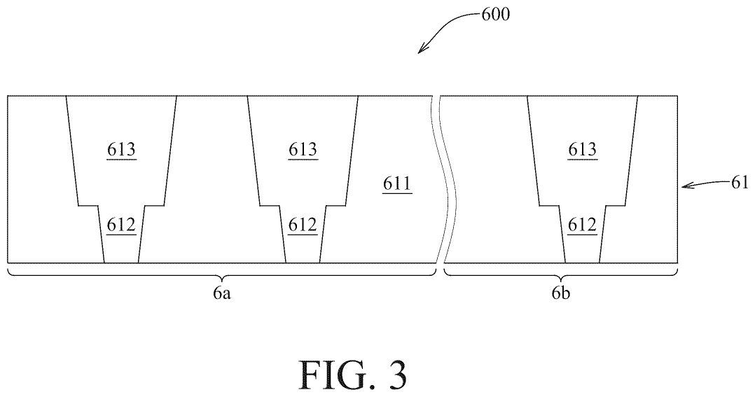

FIG. 2 is a flow chart illustrating a method 500 for manufacturing a memory device in accordance with some embodiments. FIGS. 3 to 11 are schematic sectional views of semiconductor structures 600 during various stages of the method 500. The method 500 and the semiconductor structures 600 will be described together below. It should be noted that additional steps can be provided before, during or after the method 500, and some of the steps described herein may be replaced by other steps or be eliminated. Similarly, further additional features may be present in the semiconductor structures 600, and/or features present may be replaced or eliminated in additional embodiments.

Referring to FIGS. 2 and 3, the method 500 begins at step 51, where a first interconnect structure 61 is formed. The first interconnect structure 61 includes a dielectric layer 611, a plurality of conductive vias 612 and a plurality of conductive lines 613. The dielectric layer 611, the conductive vias 612 and the conductive lines 613 of the first interconnect structure 61 would respectively serve as the dielectric layer 111, the conductive vias 112 and the conductive lines 113 of the first interconnect structure 11 of the memory device depicted in FIG. 1.

In some embodiments, the first interconnect structure 61 may be formed by: (a) depositing a first dielectric material for forming the dielectric layer 611 throughout a device memory region (6a) and a device peripheral region (6b); (b) patterning the first dielectric material to form a plurality of first recesses for accommodating the conductive lines 613 in an upper portion of the first dielectric material, where some of the first recesses are disposed in the device memory region (6a) and some of the first recesses are disposed in the device peripheral region (6b); (c) patterning the first dielectric material to form a plurality of second recesses for accommodating the conductive vias 612 in a lower portion of the first dielectric material, where some of the second recesses are disposed in the device memory region (6a), and are each in spatial communication with a corresponding one of the first recesses that are disposed in the device memory region (6a), and where some of the second recesses are disposed in the device peripheral region (6b), and are each in spatial communication with a corresponding one of the first recesses that are disposed in the device peripheral region (6b); (d) depositing a first conductive material for forming the conductive lines 613 and the conductive vias 612 on the first dielectric material, so as to fill the first recesses and the second recesses; and (e) removing superfluous first conductive material to expose the first dielectric material. The remaining portion of the first dielectric material is referred to as the dielectric layer 611. The remaining portions of the first conductive material in the first recesses are referred to as the conductive lines 613. The remaining portions of the first conductive material in the second recesses are referred to as the conductive vias 612.

In some embodiments, the first dielectric material for forming the dielectric layer 611 may be deposited using, for example, chemical vapor deposition (CVD), physical vapor deposition (PVD), other suitable techniques, or combinations thereof. In some embodiments, the first dielectric material may be made of, for example, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), porous carbon-doped silicon oxide, other suitable materials, or combinations thereof. In some other embodiments, the first dielectric material may be made of, for example, polyimide, epoxy resin, acrylic resin, phenol resin, benzocyclobutene (BCB), polybenzooxazole (PBO), other suitable polymer-based materials, or combinations thereof. In some embodiments, the dielectric layer 611 may be an interlayer dielectric (ILD) layer. In some embodiments, the first dielectric material may be patterned using a photolithography process and an etching process. The photolithography process may include, for example, but not limited to, coating a photoresist, soft-baking, exposing the photoresist through a photomask, post-exposure baking, and developing the photoresist, followed by hard-baking so as to form a patterned photoresist. The etching process may be implemented by etching the first dielectric material through the patterned photoresist using, for example, dry etching, wet etching, other suitable techniques, or combinations thereof. The patterned photoresist may be removed after the etching process. In some embodiments, the first conductive material for forming the conductive lines 613 and the conductive vias 612 may be deposited using, for example, CVD, PVD, electroless plating, electroplating, other suitable techniques, or combinations thereof. In some embodiments, the first conductive material may be made of, for example, copper, aluminum, tungsten, other suitable materials, or combinations thereof. In some embodiments, the superfluous first conductive material may be removed using, for example, chemical mechanical polishing (CMP), other suitable planarization techniques, or combinations thereof.

Referring to FIGS. 2, 4 and 5, the method 500 then proceeds to step 52, where a first barrier material 621, a second dielectric material 622 and a barrier film 623 are formed on the first interconnect structure 61.

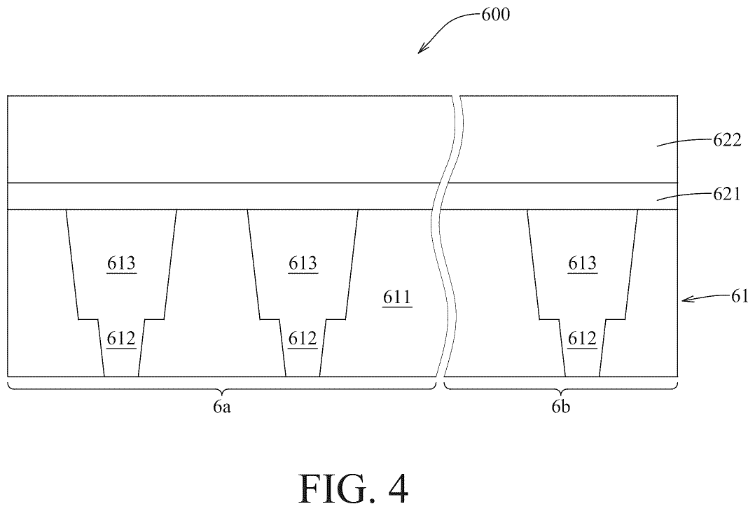

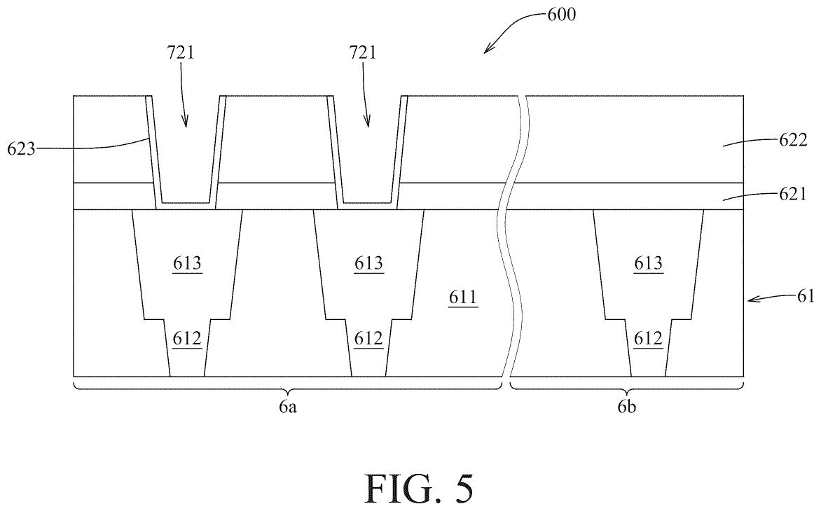

In some embodiments, the first barrier material 621, the second dielectric material 622 and the barrier film 623 may be formed by: (a) as shown in FIG. 4, depositing the first barrier material 621 on the first interconnect structure 61 using, for example, CVD, plasma-enhanced chemical vapor deposition (PECVD), atomic layer deposition (ALD), spin-on coating, electroless plating, other suitable techniques, or combinations thereof; (b) depositing the second dielectric material 622 on the first barrier material 621 using, for example, CVD, PECVD, ALD, spin-on coating, electroless plating, other suitable techniques, or combinations thereof; (c) as shown in FIG. 5, patterning the second dielectric material 622 and the first barrier material 621 using a photolithography process and an etching process similar to those used to pattern the first dielectric material for forming the dielectric layer 611 in step 51 of the method 500, so as to form a plurality of recesses 721 in the device memory region (6a), where each of the recesses 721 exposes a corresponding one of the conductive lines 613 that are disposed in the device memory region (6a); (d) as shown in FIG. 5, conformally depositing a second barrier material for forming the barrier film 623 on the second dielectric material 622 and in the recesses 721 using, for example, CVD, metal organic chemical vapor deposition (MOCVD), PVD, ALD, other suitable techniques, or combinations thereof; and (e) as shown in FIG. 5, removing superfluous second barrier material using, for example, CMP, other suitable planarization techniques, or combinations thereof, so as to expose the second dielectric material 622. The remaining portions of the second barrier material in the recesses 721 are collectively referred to as the barrier film 623.

In some embodiments, the first barrier material 621 may be made of, for example, metal nitride, metal oxide, metal carbide, silicon nitride, silicon oxide, silicon carbide, nitrogen-doped silicon carbide (NDC), silicon oxynitride, other suitable materials, or combinations thereof. In some embodiments, a thickness of the first barrier material 621 may fall within a range of from about 100 Å to about 150 Å. In some embodiments, the second dielectric material 622 may be made of, for example, TEOS, other suitable dielectric materials, or combinations thereof. In some embodiments, the barrier film 623 may be made of, for example, titanium, titanium nitride, tantalum, tantalum nitride, other suitable materials, alloys thereof, or combinations thereof.

Referring to FIGS. 2 and 6 to 8, the method 500 then proceeds to step 53, where a plurality of memory units 63 are formed. Each of the memory units 63 includes a bottom electrode via (631a), a bottom electrode (631b), an MTJ element 632′, a top electrode 633′ and a spacer 634. The bottom electrode via (631a), the bottom electrode (631b), the MTJ element 632′, the top electrode 633′ and the spacer 634 of each of the memory units 63 would respectively serve as the bottom electrode via 121, the bottom electrode 122, the MTJ element 123, the top electrode 124 and the spacer 125 of each of the memory units 12 of the memory device depicted in FIG. 1.

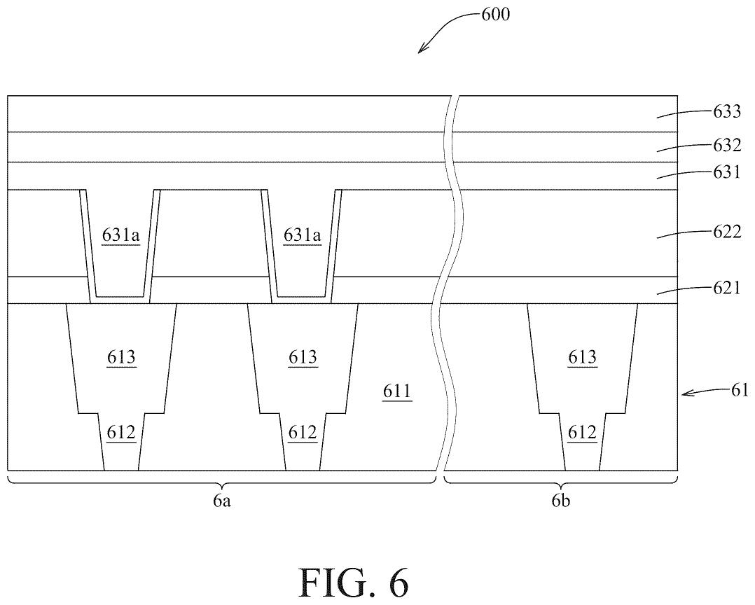

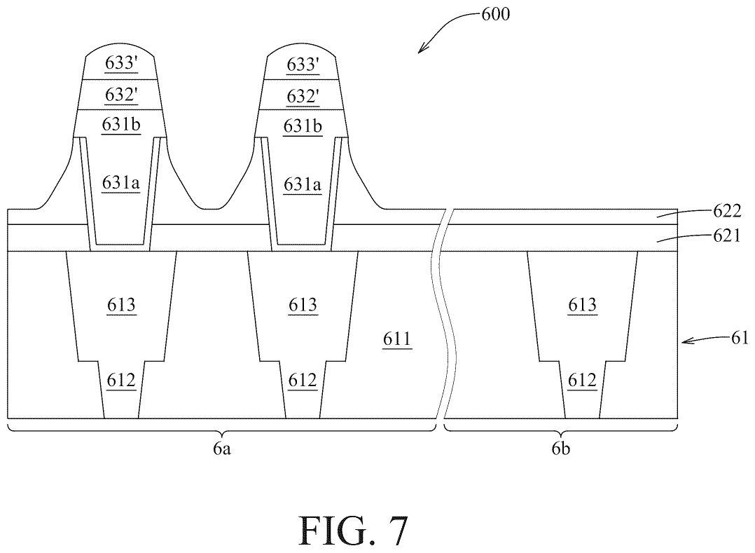

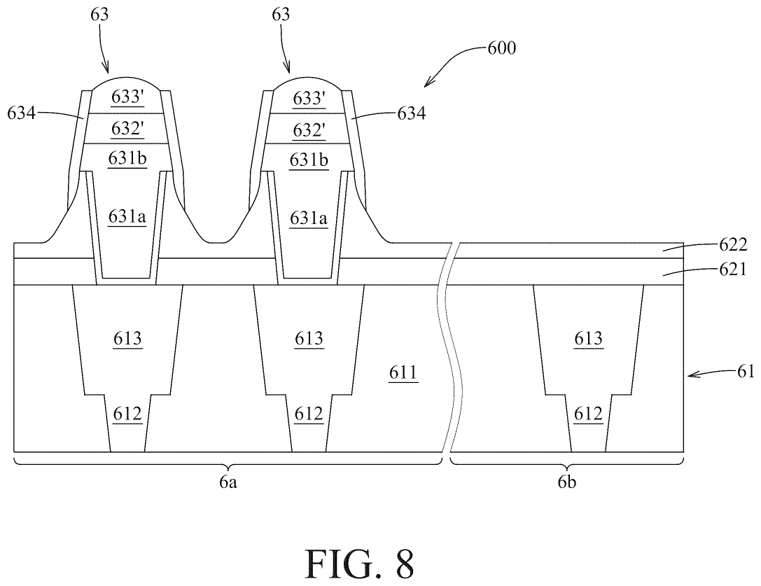

In some embodiments, the memory units 63 may be formed by: (a) as shown in FIG. 6, depositing a bottom electrode layer 631 for forming the bottom electrode vias (631a) and the bottom electrodes (631b) of the memory units 63 on the second dielectric material 622 using, for example, CVD, PVD, ALD, other suitable techniques, or combinations thereof, so as to fill the recesses 721 (see FIG. 5), where portions of the bottom electrode layer 631 that fill the recesses 721 (see FIG. 5) are referred to as the bottom electrode vias (631a) of the memory units 63; (b) as shown in FIG. 6, depositing an MTJ layer 632 for forming the MTJ elements 632′ of the memory units 63 on the bottom electrode layer 631 using, for example, CVD, PVD, ALD, plasma-enhanced ALD, molecular beam epitaxy (MBE), other suitable techniques, or combinations thereof; (c) as shown in FIG. 6, depositing a top electrode layer 633 for forming the top electrodes 633′ of the memory units 63 on the MTJ layer 632 using, for example, CVD, PVD, ALD, other suitable techniques, or combinations thereof; (d) as shown in FIGS. 6 and 7, patterning the top electrode layer 633, the MTJ layer 632, the bottom electrode layer 631 and the second dielectric material 622 using a photolithography process and an etching process similar to those used to pattern the first dielectric material for forming the dielectric layer 611 in step 51 of the method 500, so as to form the top electrodes 633′, the MTJ elements 632′ and the bottom electrodes (631b) of the memory units 63, where, with respect to each of the memory units 63, the top electrode 633′, the MTJ element 632′, the bottom electrode (631b) and the bottom electrode via (631a) are aligned with each other; (e) as shown in FIG. 8, conformally depositing a spacer layer for forming the spacers 634 of the memory units 63 on the semiconductor structure 600 depicted in FIG. 7 using, for example, CVD, PVD, ALD, other suitable techniques, or combinations thereof, so as to cover the top electrodes 633′, the MTJ elements 632′ and the bottom electrodes (631b) of the memory units 63 and the second dielectric material 622; and (f) as shown in FIG. 8, removing horizontal portions of the spacer layer using, for example, dry etching, wet etching, reactive ion etching (RIE), ion beam etching (IBE), other suitable etching techniques, or combinations thereof, so as to form the spacers 634 of the memory units 63, where, with respect to each of the memory units 63, the spacer 634 covers a side surface of each of the top electrode 633', the MTJ element 632′ and the bottom electrode (631b), and a top surface of the spacer 634 is substantially lower than a top surface of the top electrode 633′.

In some embodiments, the bottom electrode layer 631 may be made of, for example, titanium nitride, tantalum, tantalum nitride, other suitable conductive materials, or combinations thereof. In some embodiments, the MTJ layer 632 may include, from bottom to top, a reference film (i.e., a pin film) (not shown), a tunnel barrier film (not shown), a free film (not shown), a maintenance film (not shown) and a buffer film (not shown). In some other embodiments, the MTJ layer 632 may include, from bottom to top, the maintenance film, the free film, the tunnel barrier film, the reference film and the buffer film. It should be noted that the maintenance film and the buffer film may be omitted. Other suitable configurations for the MTJ layer 632 are within the contemplated scope of the present disclosure. In some embodiments, the reference film may be made of, for example, a first ferromagnetic material, such as cobalt (Co), iron (Fe), nickel (Ni), cobalt-iron alloy (CoFe), cobalt-iron-nickel alloy (CoFeNi), cobalt-boron alloy (CoB), iron-boron alloy (FeB), cobalt-iron-boron alloy (CoFeB), other suitable materials, or combinations thereof. In some embodiments, the reference film may have a single layer structure, or a multi-layered structure (e. g, (Co/X)ₙ, where X may be Ni, platinum (Pt), palladium (Pd), etc., and n is a number of the layers in the multi-layered structure and is an integer greater than two). In some embodiments, the free film may be made of, for example, a second ferromagnetic material, such as Fe, Co, Ni, CoFe, CoB, FeB, CoFeB, cobalt-iron-nickel-boron alloy (CoFeNiB), other suitable materials, or combinations thereof. In some embodiments, the free film may have a single layer structure, or a multi-layered structure that has alternately stacked ferromagnetic and non-magnetic sub-layers. In some embodiments, the tunnel barrier film may be made of, for example, a first insulating material. In some embodiments, the first insulating material may include, for example, an oxide, a nitride, an oxynitride, or combinations thereof; however, this is not a limitation of the disclosure. In some other embodiments, the first insulating material may include, for example, magnesium oxide (MgO), aluminum oxide (AlOₓ), silicon oxide (SiOₓ), titanium oxide (TiOₓ), tantalum oxide (TaOₓ), chromium oxide (CrOₓ), hafnium oxide (HfOₓ), zinc oxide (ZnO), or combinations thereof; however, this is not a limitation of the disclosure. In some embodiments, the maintenance film may be made of, for example, a second insulating material, such as an oxide (e.g., MgO or the like), other suitable materials, or combinations thereof. In some embodiments, the buffer film may be made of, for example, Ru, Ta, Mo, other suitable materials, alloys thereof, or combinations thereof. In some embodiments, the top electrode layer 633 may be made of, for example, titanium nitride, platinum, aluminum copper, gold, titanium, tantalum, tantalum nitride, tungsten, tungsten nitride, other suitable conductive material, alloys thereof, or combinations thereof. In some embodiments, the spacer layer for forming the spacers 634 of the memory units 63 may be made of, for example, silicon nitride, silicon oxide, a multilayer oxide-nitride-oxide film, un-doped silicate glass, other suitable dielectric materials, or combinations thereof.

In some embodiments, after the execution of step 53, a thickness of the second dielectric material 622 may fall within a range of from about 175 Å to about 225 Å in the device peripheral region (6b).

Referring to FIGS. 2, 9 and 10, the method 500 then proceeds to step 54, where two capping films 641', 642′ and a dielectric element 643′ are formed. The capping films 641', 642′ and the dielectric element 643′ would respectively serve as the capping films 134, 135 and the dielectric element 136 of the memory device depicted in FIG. 1.

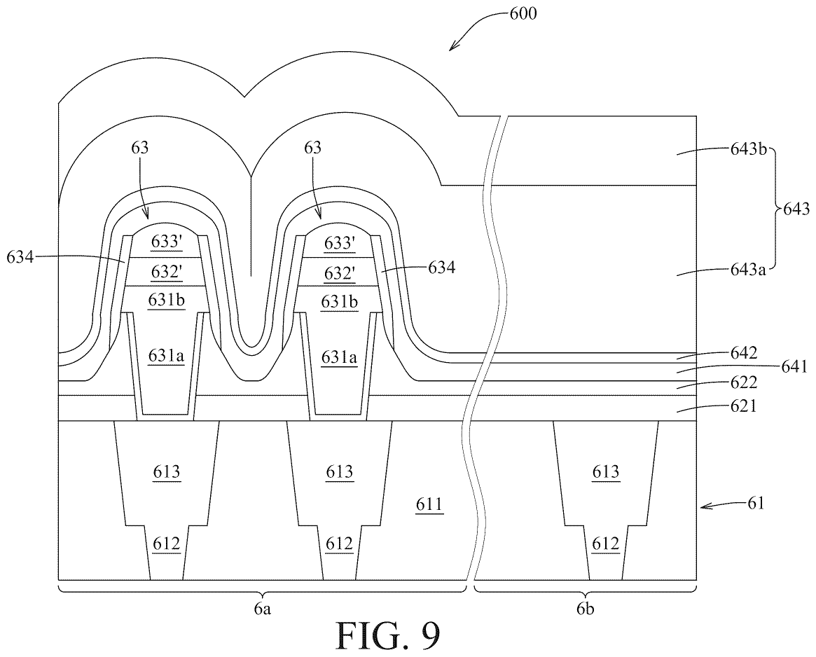

In some embodiments, the capping films 641', 642′ and the dielectric element 643′ may be formed by: (a) as shown in FIG. 9, conformally depositing an etch stop layer 641 for forming the capping film 641′ on the semiconductor structure 600 depicted in FIG. 8 using, for example, CVD, PVD, ALD, other suitable techniques, or combinations thereof, so as to cover the top electrodes 633′ and the spacers 634 of the memory units 63 and the second dielectric material 622; (b) as shown in FIG. 9, conformally depositing an etching end detection layer 642 for forming the capping film 642′ on the etch stop layer 641 using, for example, CVD, PVD, ALD, other suitable techniques, or combinations thereof; (c) as shown in FIG. 9, depositing a first layer portion (643a) of a dielectric layer 643 for forming the dielectric element 643′ on the etching end detection layer 642 using, for example, PEALD, other suitable techniques, or combinations thereof; (d) as shown in FIG. 9, depositing a second layer portion (643b) of the dielectric layer 643 on the first layer portion (643a) using, for example, CVD, PECVD, ALD, spin-on coating, electroless plating, other suitable techniques, or combinations thereof, where the second layer portion (643b) cooperates with the first layer portion (643a) to fill a spacing among the memory units 63; and (e) removing horizontal portions of each of the second layer portion (643b), the first layer portion (643a), the etching end detection layer 642 and the etch stop layer 641 using, for example, RIE, other suitable etching techniques, or combinations thereof, so as to expose top surfaces of the top electrodes 633′ of the memory units 63 and a portion of the second dielectric material 622 that is not close to the memory units 63 (e.g., a portion of the second dielectric material 622 that is disposed in the device peripheral region (6b)). The remaining portion of the etch stop layer 641 is referred to as the capping film 641′. The remaining portion of the etching end detection layer 642 is referred to as the capping film 642′. The remaining portion of the dielectric layer 643 is referred to as the dielectric element 643′. A top surface of each of the capping films 641′, 642′ and the dielectric layer 643 is substantially lower than the top surfaces of the top electrodes 633′ of the memory units 63. In some embodiments, the horizontal portions of each of the second layer portion (643b), the first layer portion (643a) and the etching end detection layer 642 may be removed using a first etchant, the horizontal portions of the etch stop layer 641 may be removed using a second etchant, each of the first etchant and the second etchant may be a fluorine-based gas, and a fluorine concentration of the first etchant may be different from a fluorine concentration of the second etchant. In some embodiments, the removing of the horizontal portions of each of the second layer portion (643b), the first layer portion (643a) and the etching end detection layer 642 may be terminated at a time instant where a predetermined time interval elapses after detection of the etching end detection layer 642, so as to expose the etch stop layer 641. In some embodiments, the dielectric layer 643 may have a single layer structure, instead of the multi-layered structure as shown in FIG. 9.

In some embodiments, the etch stop layer 641 may be made of, for example, a silicon compound that does not contain nitrogen (N) atoms, such as silicon oxycarbide or the like. Other suitable materials are within the contemplated scope of the present disclosure. In some embodiments, the etching end detection layer 642 may be made of, for example, a nitride, such as a silicon compound that contains nitrogen atoms (e.g., silicon nitride, silicon oxynitride or the like). Other suitable materials are within the contemplated scope of the present disclosure. In some embodiments, the first layer portion (643a) and the second layer portion (643b) may be made of different dielectric materials. In some embodiments, the first layer portion (643a) may be made of, for example, an oxide. Other suitable materials are within the contemplated scope of the present disclosure. In some embodiments, the second layer portion (643b) may be made of, for example, TEOS. Other suitable materials are within the contemplated scope of the present disclosure.

In some embodiments, before the removing of the horizontal portions of each of the second layer portion (643b), the first layer portion (643a), the etching end detection layer 642 and the etch stop layer 641, a thickness of the etch stop layer 641 may fall within a range of from about 125 Å to about 175 Å, a thickness of the etching end detection layer 642 may fall within a range of from about 175 Å to about 225 Å, a thickness of the first layer portion (643a) may fall within a range of from about 650 Å to about 750 Å, and a thickness of the second layer portion (643b) may fall within a range of from about 275 Å to about 325 Å.

Referring to FIGS. 2, 10 and 11, the method 500 then proceeds to step 55, where a second interconnect structure 65 is formed. The second interconnect structure 65 includes a dielectric layer 651, a plurality of conductive vias 652 and a plurality of conductive lines 653. The dielectric layer 651, the conductive vias 652 and the conductive lines 653 of the second interconnect structure 65 would respectively serve as the dielectric layer 141, the conductive vias 142 and the conductive lines 143 of the second interconnect structure 14 of the memory device depicted in FIG. 1.

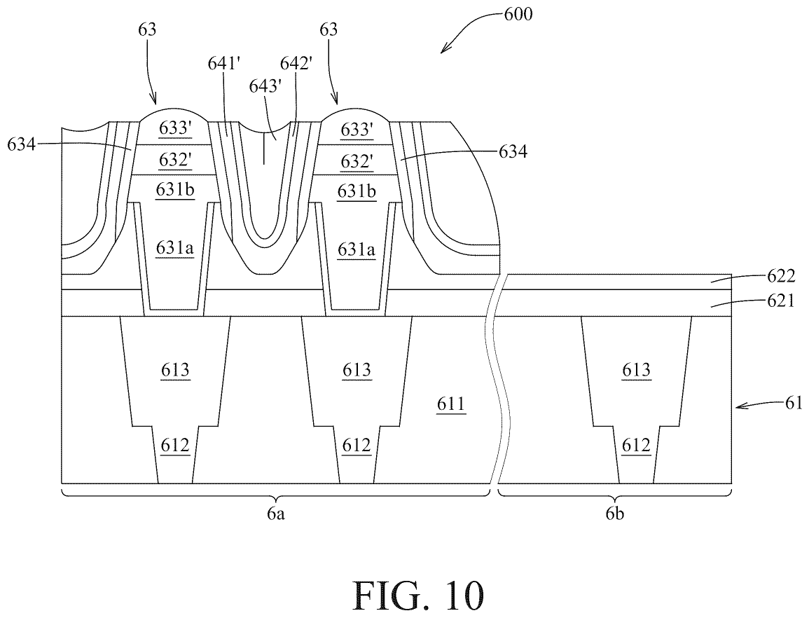

In some embodiments, the second interconnect structure 65 may be formed by: (a) depositing a third dielectric material for forming the dielectric layer 651 on the semiconductor structure 600 depicted in FIG. 10; (b) patterning the third dielectric material to form a plurality of third recesses for accommodating the conductive lines 653 in an upper portion of the third dielectric material, where some of the third recesses are disposed in the device memory region (6a), and are each aligned with a corresponding one of the top electrodes 633′ of the memory units 63, and where some of the third recesses are disposed in the device peripheral region (6b), and are each aligned with a corresponding one of the conductive lines 613 that are disposed in the device peripheral region (6b); (c) patterning the third dielectric material, the second dielectric material 622 and the first buffer material 621 to form a plurality of fourth recesses for accommodating the conductive vias 652 in a lower portion of the third dielectric material, where some of the fourth recesses are disposed in the device memory region (6a), are each in spatial communication with a corresponding one of the third recesses that are disposed in the device memory region (6a), and are each exposing a corresponding one of the top electrodes 633′ of the memory units 63, and where some of the second recesses are disposed in the device peripheral region (6b), are each in spatial communication with a corresponding one of the third recesses that are disposed in the device peripheral region (6b), and are each exposing a corresponding one of the conductive lines 613 that are disposed in the device peripheral region (6b); (d) depositing a second conductive material for forming the conductive lines 653 and the conductive vias 652 on the third dielectric material, so as to fill the third recesses and the fourth recesses; and (e) removing superfluous second conductive material to expose the third dielectric material. The remaining portion of the third dielectric material is referred to as the dielectric layer 651. The remaining portions of the second conductive material in the third recesses are referred to as the conductive lines 653. The remaining portions of the second conductive material in the fourth recesses are referred to as the conductive vias 652. The remaining portion of the second dielectric material 622 is referred to as a dielectric layer 622′, and would serve as the dielectric layer 132 of the memory device depicted in FIG. 1. The remaining portion of the first buffer material 621 is referred to as a buffer layer 621′, and would serve as the buffer layer 131 of the memory device depicted in FIG. 1.

In some embodiments, the third dielectric material for forming the dielectric layer 651 may be deposited using, for example, CVD, PVD, other suitable techniques, or combinations thereof. In some embodiments, the third dielectric material may be made of, for example, silicon oxide, silicon nitride, silicon carbide, silicon oxycarbide, silicon oxynitride, silicon carbonitride, silicon oxycarbonitride, USG, PSG, BSG, BPSG, FSG, porous carbon-doped silicon oxide, other suitable materials, or combinations thereof. In some other embodiments, the third dielectric material may be made of, for example, polyimide, epoxy resin, acrylic resin, phenol resin, BCB, PBO, other suitable polymer-based materials, or combinations thereof. In some embodiments, the dielectric layer 651 may be an ILD layer. In some embodiments, the third dielectric material, the second dielectric material 622 and the first buffer material 621 may be patterned using a photolithography process and an etching process similar to those used to pattern the first dielectric material for forming the dielectric layer 611 in step 51 of the method 500. In some embodiments, the second conductive material for forming the conductive lines 653 and the conductive vias 652 may be deposited using, for example, CVD, PVD, electroless plating, electroplating, other suitable techniques, or combinations thereof. In some embodiments, the second conductive material may be made of, for example, copper, aluminum, tungsten, other suitable materials, or combinations thereof. In some embodiments, the superfluous second conductive material may be removed using, for example, CMP, other suitable planarization techniques, or combinations thereof.

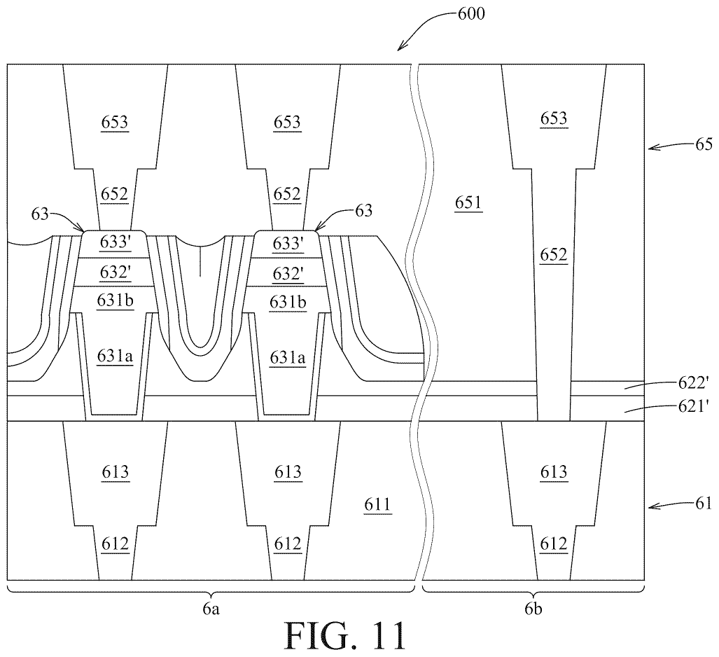

Referring to FIGS. 9 to 11, in view of the above, the horizontal portions of each of the dielectric layer 643, the etching end detection layer 642 and the etch stop layer 641 can be easily removed to expose the top surface of each of the top electrodes 633′ of the memory units 63, so each of the conductive vias 652 can be in contact with the corresponding top electrode 633′, thereby improving yield of a memory device that includes the semiconductor structure 600 depicted in FIG. 11. In addition, the horizontal portions of each of the dielectric layer 643, the etching end detection layer 642 and the etch stop layer 641 can be removed without an additional photoresist, so cost of the memory device can be reduced.

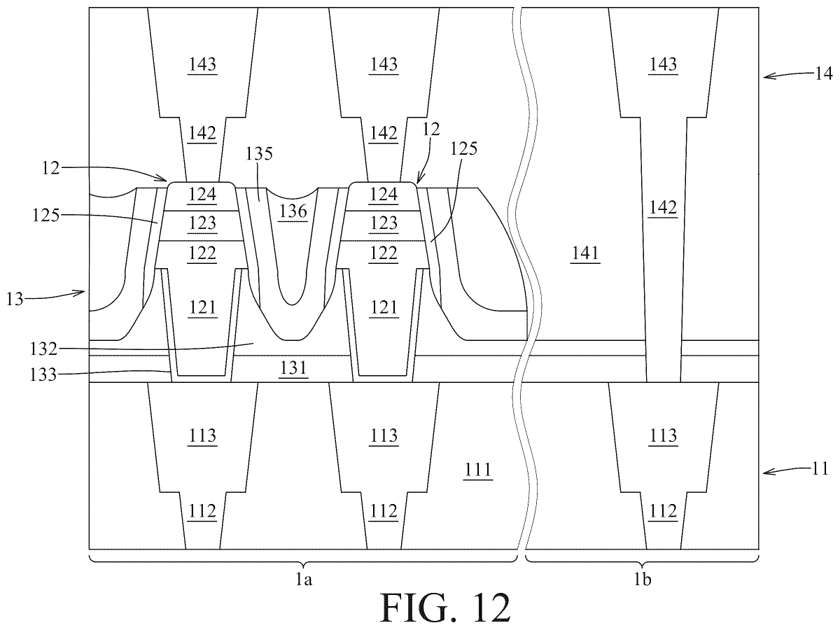

FIG. 12 is a schematic sectional view of a semiconductor device in accordance with some embodiments. Referring to FIG. 12, the memory device depicted in FIG. 12 is similar to the memory device depicted in FIG. 1, but differs from the memory device depicted in FIG. 1 in that the capping film 134 (see FIG. 1) is omitted, and the capping film 135 is in contact with the spacers 125 of the memory units 12. In addition, the memory device depicted in FIG. 12 may be manufactured by the method 500 shown in FIG. 2, where a capping layer is formed in step 54.

In accordance with some embodiments of the present disclosure, a method for manufacturing a memory device includes: forming a memory unit that includes a bottom electrode, an MTJ element disposed on the bottom electrode, and a top electrode disposed on the MTJ element; forming an etch stop layer over the memory unit, wherein the etch stop layer is disposed along a top surface and a side surface of the memory unit, and is made of a silicon compound; forming an etching end detection layer on the etch stop layer, wherein the etching end detection layer is made of a nitride; forming a dielectric layer on the etching end detection layer; and removing a horizontal portion of each of the dielectric layer, the etching end detection layer and the etch stop layer, so as to expose the top surface of the memory unit.

In accordance with some embodiments of the present disclosure, the dielectric layer is formed by depositing a first layer portion of the dielectric layer on the etching end detection layer, and depositing a second layer portion of the dielectric layer on the first layer portion. The first layer portion and the second layer portion are made of different dielectric materials.

In accordance with some embodiments of the present disclosure, the first layer portion is made of an oxide, and the second layer portion is made of tetra-ethyl-ortho-silicate.

In accordance with some embodiments of the present disclosure, the horizontal portion of each of the dielectric layer, the etching end detection layer and the etch stop layer are removed by removing the horizontal portion of each of the dielectric layer and the etching end detection layer using a first etchant, and removing the horizontal portion of the etch stop layer using a second etchant. Each of the first etchant and the second etchant is a fluorine-based gas. A fluorine concentration of the first etchant is different from a fluorine concentration of the second etchant.

In accordance with some embodiments of the present disclosure, the etch stop layer is made of a silicon compound that does not contain nitrogen atoms.

In accordance with some embodiments of the present disclosure, after the horizontal portion of each of the dielectric layer, the etching end detection layer and the etch stop layer is removed, the top surface of the memory device is higher than a top surface of a remaining portion of each of the dielectric layer, the etching end detection layer and the etch stop layer.

In accordance with some embodiments of the present disclosure, the memory unit further includes a spacer that covers a side surface of each of the bottom electrode, the MTJ element and the top electrode, and the etch stop layer is disposed along a top surface of the top electrode and the spacer of the memory unit.

In accordance with some embodiments of the present disclosure, a method for manufacturing a memory device includes: forming a memory unit that includes a bottom electrode, a data storage element disposed on the bottom electrode, and a top electrode disposed on the data storage element; forming an etching end detection layer over the memory unit, wherein the etching end detection layer is disposed along a top surface and a side surface of the memory device; forming a dielectric layer on the etching end detection layer; and removing a horizontal portion of each of the dielectric layer and the etching end detection layer, so as to expose the top surface of the memory unit.

In accordance with some embodiments of the present disclosure, the dielectric layer is formed by depositing a first layer portion of the dielectric layer on the etching end detection layer, and depositing a second layer portion of the dielectric layer on the first layer portion. The first layer portion and the second layer portion are made of different dielectric materials.

In accordance with some embodiments of the present disclosure, the first layer portion is made of an oxide, and the second layer portion is made of tetra-ethyl-ortho-silicate.

In accordance with some embodiments of the present disclosure, the horizontal portion of each of the dielectric layer and the etching end detection layer are removed using a fluorine-based gas.

In accordance with some embodiments of the present disclosure, the etching end detection layer is made of silicon nitride.

In accordance with some embodiments of the present disclosure, the etching end detection layer is made of silicon oxynitride.

In accordance with some embodiments of the present disclosure, after the horizontal portion of each of the dielectric layer and the etching end detection layer is removed, the top surface of the memory device is higher than a top surface of a remaining portion of each of the dielectric layer and the etching end detection layer.

In accordance with some embodiments of the present disclosure, a memory device includes a memory unit, a first capping film and a dielectric element. The memory unit includes a bottom electrode, an MTJ element disposed on the bottom electrode, and a top electrode disposed on the MTJ element. The first capping film laterally surrounds the memory unit, and exposes a top surface of the memory unit. The dielectric element laterally surrounds the first capping film.

In accordance with some embodiments of the present disclosure, the memory unit further includes a spacer that covers a side surface of each of the bottom electrode, the MTJ element and the top electrode. The first capping film is disposed along the spacer of the memory unit.

In accordance with some embodiments of the present disclosure, the first capping film is made of a nitride.

In accordance with some embodiments of the present disclosure, the memory device further includes a second capping film disposed between the first capping film and the dielectric element.

In accordance with some embodiments of the present disclosure, the first capping film is made of a silicon compound that does not contain nitrogen atoms, and the second capping film is made of a nitride.

In accordance with some embodiments of the present disclosure, a top surface of the memory unit is higher than a top surface of each of the first capping film and the dielectric element.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a memory device, comprising:
forming a memory unit that includes
a bottom electrode,
a magnetic tunnel junction (MTJ) element disposed on the bottom electrode,
and
a top electrode disposed on the MTJ element;
forming an etch stop layer over the memory unit, wherein the etch stop layer is disposed along a top surface and a side surface of the memory unit, and is made of a silicon compound;
forming an etching end detection layer on the etch stop layer, wherein the etching end detection layer is made of a nitride;
forming a dielectric layer on the etching end detection layer; and
removing a horizontal portion of each of the dielectric layer, the etching end detection layer and the etch stop layer, so as to expose the top surface of the memory unit.

2. The method according to claim 1, wherein:
the dielectric layer is formed by
depositing a first layer portion of the dielectric layer on the etching end detection layer, and
depositing a second layer portion of the dielectric layer on the first layer portion; and
the first layer portion and the second layer portion are made of different dielectric materials.

3. The method according to claim 2, wherein:
the first layer portion is made of an oxide; and
the second layer portion is made of tetra-ethyl-ortho-silicate.

4. The method according to claim 1, wherein:
the horizontal portion of each of the dielectric layer, the etching end detection layer and the etch stop layer are removed by
removing the horizontal portion of each of the dielectric layer and the etching end detection layer using a first etchant, and
removing the horizontal portion of the etch stop layer using a second etchant;
each of the first etchant and the second etchant is a fluorine-based gas; and
a fluorine concentration of the first etchant is different from a fluorine concentration of the second etchant.

5. The method according to claim 1, wherein:
the etch stop layer is made of a silicon compound that does not contain nitrogen atoms.

6. The method according to claim 1, wherein:
after the horizontal portion of each of the dielectric layer, the etching end detection layer and the etch stop layer is removed, the top surface of the memory device is higher than a top surface of a remaining portion of each of the dielectric layer, the etching end detection layer and the etch stop layer.

7. The method according to claim 1, wherein:
the memory unit further includes a spacer that covers a side surface of each of the bottom electrode, the MTJ element and the top electrode; and
the etch stop layer is disposed along a top surface of the top electrode and the spacer of the memory unit.

8. A method for manufacturing a memory device, comprising:
forming a memory unit that includes
a bottom electrode,
a data storage element disposed on the bottom electrode, and
a top electrode disposed on the data storage element;
forming an etching end detection layer over the memory unit, wherein the etching end detection layer is disposed along a top surface and a side surface of the memory unit;
forming a dielectric layer on the etching end detection layer; and
removing a horizontal portion of each of the dielectric layer and the etching end detection layer, so as to expose the top surface of the memory unit.

9. The method according to claim 8, wherein:
the dielectric layer is formed by
depositing a first layer portion of the dielectric layer on the etching end detection layer, and
depositing a second layer portion of the dielectric layer on the first layer portion; and
the first layer portion and the second layer portion are made of different dielectric materials.

10. The method according to claim 9, wherein:
the first layer portion is made of an oxide; and
the second layer portion is made of tetra-ethyl-ortho-silicate.

11. The method according to claim 8, wherein:
the horizontal portion of each of the dielectric layer and the etching end detection layer are removed using a fluorine-based gas.

12. The method according to claim 8, wherein:
the etching end detection layer is made of silicon nitride.

13. The method according to claim 8, wherein:
the etching end detection layer is made of silicon oxynitride.

14. The method according to claim 8, wherein:
after the horizontal portion of each of the dielectric layer and the etching end detection layer is removed, the top surface of the memory device is higher than a top surface of a remaining portion of each of the dielectric layer and the etching end detection layer.

15. A memory device comprising:
a memory unit including
a bottom electrode,
a magnetic tunnel junction (MTJ) element disposed on the bottom electrode,
and
a top electrode disposed on the MTJ element;
a first capping film laterally surrounding the memory unit, and exposing a top surface of the memory unit; and
a dielectric element laterally surrounding the first capping film.

16. The memory device according to claim 15, wherein:
the memory unit further includes a spacer that covers a side surface of each of the bottom electrode, the MTJ element and the top electrode; and
the first capping film is disposed along the spacer of the memory unit.

17. The memory device according to claim 15, wherein:
the first capping film is made of a nitride.

18. The memory device according to claim 15, further comprising:
a second capping film disposed between the first capping film and the dielectric element.

19. The memory device according to claim 18, wherein:
the first capping film is made of a silicon compound that does not contain nitrogen atoms; and
the second capping film is made of a nitride.

20. The memory device according to claim 15, wherein:
a top surface of the memory unit is higher than a top surface of each of the first capping film and the dielectric element.
